(19) United States
(12) Patent Application Publication
(10) Pub. No.: US 2016/0163629 A1
(43) Pub. Date: Jun. 9, 2016

(54) SEMICONDUCTOR PACKAGE AND METHOD OF FABRICATING THE SAME

(71) Applicant: PHOENIX PIONEER TECHNOLOGY CO., LTD, Hsinchu County (TW)

(72) Inventors: Shih-Ping Hsu, Hsinchu County (TW); Tang-I Wu, Hsinchu County (TW)

(21) Appl. No.: 14/801,099

(22) Filed: Jul. 16, 2015

(30) Foreign Application Priority Data
Dec. 3, 2014 (CN) 201410727443.0

(51) Int. Cl. H01L 23/498; H01L 23/00; H01L 21/56; H01L 23/31; H01L 21/48

(52) U.S. Cl. CPC H01L 23/49827; H01L 23/3114; H01L 21/486; H01L 23/49838; H01L 21/56; H01L 24/81; H01L 24/16; H01L 2224/81193; H01L 2224/16238

(57) ABSTRACT

A method of fabricating a package structure is provided, including forming a plurality of conductive pillars on a conductive layer, forming an insulating layer on the conductive layer and the conductive pillars, removing a portion of the conductive layer to allow the remaining portion of the conductive layer to serve as a wiring layer, disposing at least one electronic component on the wiring layer, and forming on the wiring layer and insulation layer an encapsulating layer to encapsulate the electronic component. Therefore, as there is already a wiring layer the wiring layer is capable of being integrated with the electronic component for allowing the conductive pillars to be bonded with solder balls to thereby shorten the signal transmission path. The present invention further provides a package structure thus fabricated.

### BACKGROUND OF THE INVENTION

1. Field of the Invention The present invention relates to package structures, and, more particularly, to a package structure having a wiring layer and a method of fabricating the package structure.

2. Description of Related Art

As the semiconductor packaging technology advances, several packaging types of electronic products have been developed, including ball grid array (BGA), quad-flat package (QFD) and quad flat nonlead package (QFN), which can be incorporated in electronic devices, such as smart phones, tablets, internets, and laptops.

As shown in FIG. 1A, a conventional QFP package structure 1 comprises a carrier 10, a plurality of leads 11 formed around the periphery of the carrier 10, electronic components 12 mounted on the carrier 10 and electrically connected to the leads 11 via a plurality of bonding wires 120, and an insulating layer 13 such as an encapsulant that encapsulates the electronic components 12, the carrier 10, the bonding wires 120 and the leads 11, wherein the leads 11 protrudes from the insulating layer 13.

However, in the method of fabricating the conventional QFD package 1, since the carrier 10 and the leads 11 of the lead frame are preformed, wirings and input/output (I/O) connections are subject to certain limitation. For instance, in a conventional lead frame if the lead 11 is 400 μm in length, and the carrier 10 is 125 μm in length the number of I/O connections and the pitch of the leads 11 are undesirably limited.

Moreover, during a packaging process, due to the fixed size of the lead frame and the height of the bonding wires 120, the conventional QFP package structure 1 is thick as a whole, and it is difficult to make it thinner.

As shown in FIG. 1B, more I/O connections can be accommodated in the packaging substrate of another conventional BGA package structure 1′ that meets the need for chips with high integration. The package structure 1′ comprises: a carrier 10′, wiring layers 11a and 11b formed on the upper side 10a and the lower side 10b of the carrier 10′, respectively, an electronic component 12 disposed on the upper side 10a and electrically connected with the wiring layer 11a via a plurality of conductive bumps 120′, an insulating layer 13 such as an underfill that encapsulates the conductive bumps 120′, and conductive elements 14 such as solder balls formed on the wiring layer 11b on the lower surface 10b of the carrier 10′. Conductive pillars 100 are further formed in the carrier 10′ and electrically connected with the wiring layers 11a and 11b. Therefore, in order to reach high lead number, the electronic components 12 are electrically connected to the carrier 10′ via bonding wires or in a flip chip manner, and the conductive elements 14 are implanted on the wiring layer 11b on the lower side 10b of the carrier 10′ for external electronic devices to be electrically connected therewith.

However, in the conventional BGA package structure 1′, it is difficult to further enhance the electrical performance during higher frequency use or high speed operation, due to the long signal transmission path (formed by the conductive elements 14, the wiring layers 11a and 11b, and the conductive pillars 100).

Moreover, at least two wiring layers 11a and 11b and the conductive pillars 100 are required to be fabricated in the conventional BGA package structure 1′ (including drilling vias and platting copper material in the vias to form the connection means between the two layers). Hence, the overall structure is far from satisfying the low-profile requirement, and due to the complex fabricating process and prolonged procedures, it is difficult to reduce the overall fabricating cost.

Moreover, because more electrical connection interfaces are generated (such as those between the conductive elements 14, the two wiring layers 11a and 11b and the conductive pillars 100) in the conventional BGA package structure 1′, and a carrier 10′ having multiple layers made of different materials is required, delamination of the interfaces tends to occur and the fabricating cost is accordingly increased.

As the carrier 10′ is made of materials having different thermal expansion coefficients (CTE), it is easy to cause warpage to take place particularly in the interface between the two layers having different CTEs.

Thus, there is an urgent need for solving the foregoing problems.

### SUMMARY OF THE INVENTION

In view of the foregoing drawbacks of the prior art, the present invention provides a package structure, comprising: an insulating layer having opposing first and second surfaces; a plurality of conductive pillars embedded in the insulating layer and having terminal surfaces exposed from the first surface of the insulating layer; a wiring layer formed on the second surface of the insulating layer and electrically connected with the conductive pillars; at least one electronic component disposed on and electrically connected with the wiring layer; and an encapsulating layer formed on the wiring layer and the second surface of the insulating layer and encapsulating the electronic components.

The present invention further provides a method of fabricating a package structure, comprising: forming a plurality of conductive pillars on a conductive layer; forming on the conductive layer and the conductive pillars an insulating layer that has opposing first and second surfaces, with terminal surfaces of the conductive pillars exposed from the first surface of the insulating layer; removing a portion of the conductive layer, such that a remaining portion of the conductive layer serves as a wiring layer; disposing on the wiring layer at least one electronic component that is electrically connected with the wiring layer; and forming on the wiring layer and the second surface of the insulating layer an encapsulating layer that encapsulates the electronic component.

The present invention further provides another method of fabricating a package structure, comprising: forming a plurality of conductive pillars on a conductive layer; forming on the conductive layer and the conductive pillars an insulating layer that has opposing first and second surfaces, with the conductive pillars covered by the insulating layer completely; removing a portion of the insulating layer, to allow terminal surfaces of the conductive pillars to be exposed from the first surface of the insulating layer; removing a portion of the conductive layer, such that a remaining portion of the conductive layer serves as a wiring layer; disposing on the wiring layer at least one electronic component that is electrically connected with the wiring layer; and forming on the wiring layer and the second surface of the insulating layer an encapsulating layer that encapsulates the at least one electronic component.

In summary, in the package structure and the method of fabricating the same according to the present invention, only one wiring layer 20′ is required to be formed. With the conductive pillars serving as external connection pads, the wiring layer coupled to the electronic component and the conductive pillars coupled to solder balls, the length of the signal transmission pathway and signal loss are reduced, and the electrical performance can be enhanced.

Further, since the package structure according to the present invention is provided with a plurality of conductive pillars on a single wiring layer, the terminal surfaces of the conductive pillars function as external connection pads, without the need of fabricating another wiring layer. Therefore, the processes such as a drilling process, a filling process, a process of fabricating a second wiring layer can be omitted, such that not only the overall structure of the package but also the fabricating cost can be greatly reduced.

Furthermore, since the package structure of the present invention is provided with a connection interface between the wiring layer and the conductive pillars, the number of interfaces is less compared to the prior art, and as a result the problem of delamination can be prevented. In addition as the conductive layer is directly patterned to form the wiring layer, the fabricating cost can be greatly reduced.

### BRIEF DESCRIPTION OF THE DRAWINGS

FIG. 1A is a cross-sectional schematic view of a conventional QFP package structure;

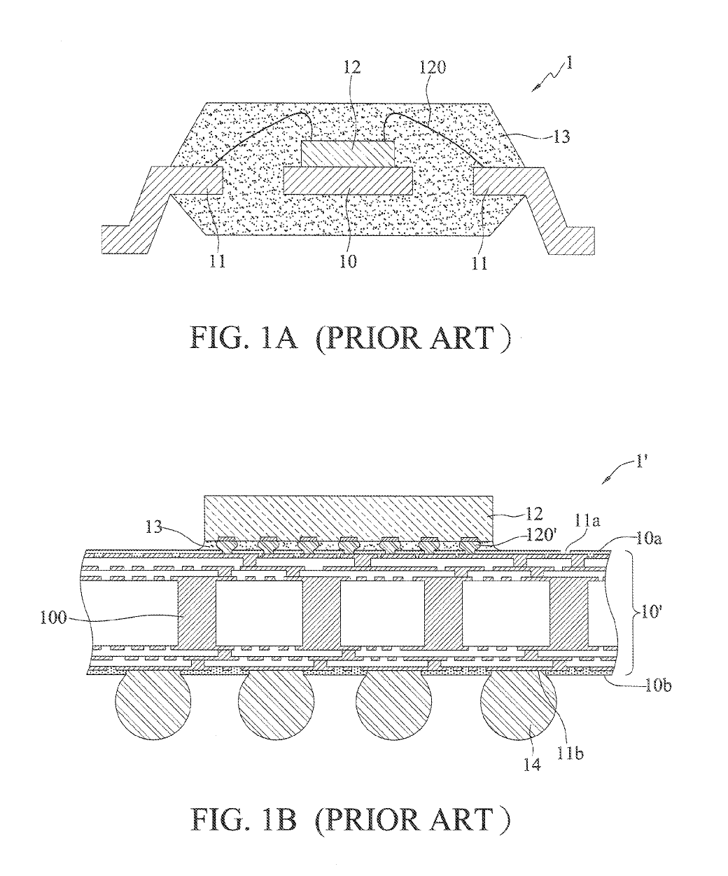

FIG. 1B is a cross-sectional schematic view of a conventional BGA package structure; and

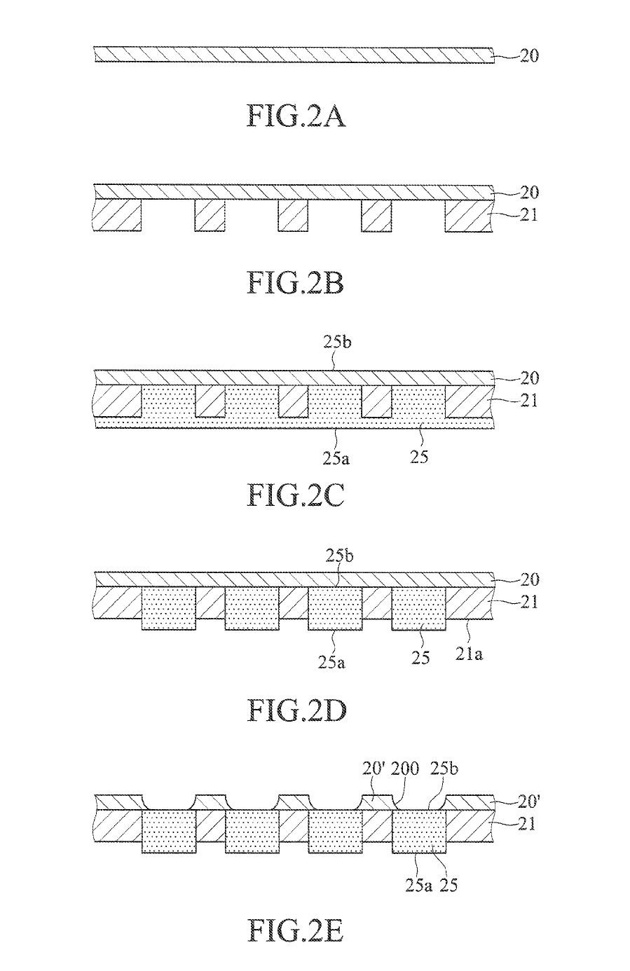

FIGS. 2A-2H are cross-sectional views showing a method of fabricating a package structure according to the present invention.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “top”, “first”, “second”, “one” and etc., are merely for illustrative purpose and should not be construed to limit the scope of the present invention.

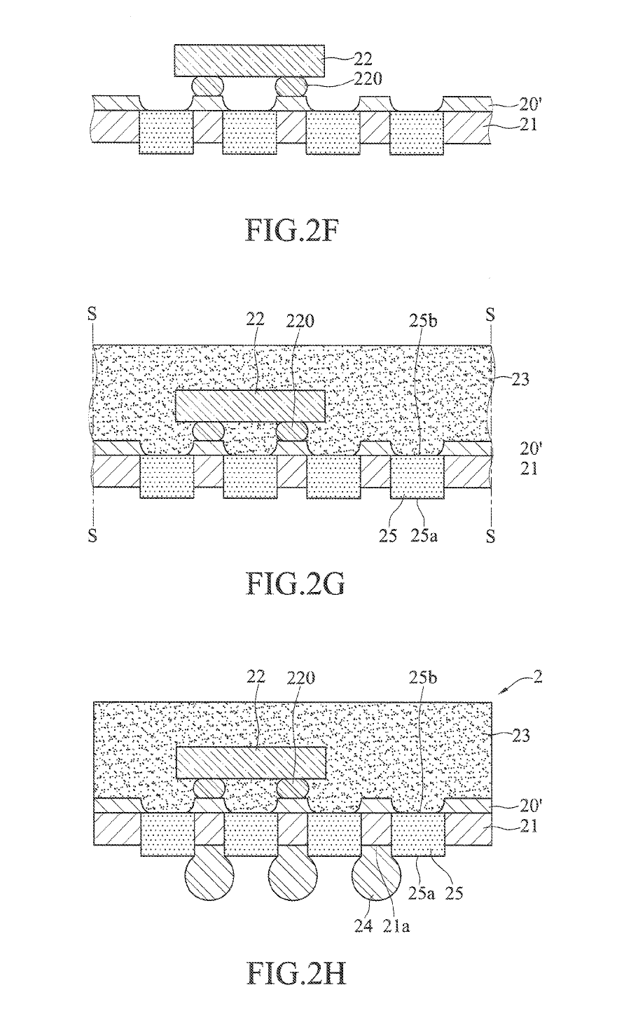

FIGS. 2A-2F are cross-sectional views showing a method of fabricating a package structure 2 according to the present invention.

As shown in FIG. 2A, a conductive layer 20 is provided. In an embodiment, the conductive layer 20 is made of, but not limited to, a metal material such as copper.

As shown in FIG. 2B, a plurality of conductive pillars 21 are formed on the conductive layer 20.

As shown in FIG. 2C, an insulating layer 25 is formed on the conductive layer 20 and the conductive pillars, and covers the conductive pillars 21 completely. The insulating layer 25 has a first surface 25a and an opposing second surface 25b.

In an embodiment, the insulating layer 25 is made of a primer or a dielectric material.

As shown in FIG. 2D, a portion of the first surface 25a of the insulating layer 25 is removed, allowing the terminal surfaces 21a of the conductive pillars 21 to be exposed from the first surface 25a of the insulating layer 25.

A grinding process (such as a method of grinding the insulating layer 25) can be employed in other embodiment, such that the terminal surfaces of the conductive pillars are flush with the first surface of the insulating layer.

As shown in FIG. 2E, a patterning process is performed to remove a portion of the conductive layer 20 and a portion of the second surface 25b of the insulating layer 25, to pattern the conductive layer 20 to be the wiring layer 20′, such that a portion of the second surface 25b of the insulating layer 25 is exposed from the wiring layer 20′. In an embodiment, the wiring layer 20′ is electrically connected with the conductive pillars 21.

Further, a patterning process is performed by an etching method, to make the second surface 20b of the wiring layer 20′ to have a concaved structure 200.

As shown in FIG. 2F, at least one electronic component 22 is mounted on the wiring layer 20′, and electrically connected with the wiring layer 20′.

In an embodiment, the electronic component is an active component, a passive component, or a combination thereof. The active component can be a semiconductor element such as a chip, and the passive component can be a resistor, a capacitor or an inductor.

Furthermore, the electronic component 22 is electrically connected with the conductive pillars 21 via the plurality of conductive bumps 220 which are electrically connected with the wiring layer 20′.

As shown in FIG. 2G, an encapsulating layer 23 is formed on the wiring layer 20′ and the exposed portion of the second surface 25b of the insulating layer 25, and covers the electronic components 22 and the conductive bumps 220.

In an embodiment, the encapsulating layer 23 is formed on the carrier 20 by a molding, a coating or a lamination method. The encapsulating layer 23 is made of a molding compound, a primer or a dielectric material such as epoxy.

In an embodiment, the top surface of the electronic element can be exposed from the top surface of the encapsulating layer 23.

In an embodiment, an underfill (not shown) can be formed to cover the conductive bumps 220 before the encapsulating layer 23 is formed.

As shown in FIG. 2H, a plurality of conductive elements 24 such as solder balls are formed on the first surface 25a of the insulating layer 25, and a singulation process is performed to cut along the S pathway to complete the fabrication of a plurality of package structures 2.

In an embodiment, the conductive elements 24 are coupled and electrically connected to the terminal surfaces 21a of the conductive pillars, for other electronic devices (not shown) to be stacked thereon.

In a package structure and a method of fabricating the same according to the present invention, only one wiring layer 20′ is required to be fabricated. With the conductive pillars 21 serving as external connection pads, the wiring layer 20′ coupled to the electronic component 22, and the conductive pillars 21 coupled to conductive elements 24, the signal transmission pathway and signal loss are reduced and the electrical performance can be enhanced.

Further, since the package structure 2 according to the present invention is provided with a plurality of conductive pillars 21 on one layer of the wiring layer, the terminal surfaces 21 a of the conductive pillars 21 may function as external connection pads, without the need of fabricating another layer of wiring layer. Therefore, the processes such as a drilling process, a filling process, a process of fabricating a second wiring layer can be omitted, such that not only the overall structure of the package 2 meets the low profile demand but also the fabricating cost can be greatly reduced.

Furthermore, since the package structure 2 according to the present invention is provided with a connection interface, the number of interfaces is less compared to the prior art, thereby reducing the possibility of delamination. In addition as the conductive layer is directly patterned to form the wiring layer, the fabricating cost can be greatly reduced.

Further, the insulating layer 25 according the present invention is made of a single material, rather than hybrid materials, as used in the conventional carrier board, the insulating layer 25 is prevented from warpage as a result of uneven stress.

The present invention further provides a package structure 2, comprising: an insulating layer 25, a plurality of conductive pillars, a wiring layer 20′, at least one electronic component 22, and an encapsulating layer 23.

The insulating layer 25 has a first surface 25a and an opposing second surface 25b.

The conductive pillars 21 are embedded in the insulating layer 25, and have terminal surfaces 21a exposed from the first surface 25a of the insulating layer 25.

The wiring layer 20′ is embedded in the second surface 25b of the insulating layer 25 and electrically connected with the conductive pillars 21.

The electronic component 22 is formed on the wiring layer 20′ and electrically connected with the wiring layer 20′. In an embodiment, the electronic component is an active component, a passive component, or a combination thereof, and is electrically connected with the wiring layer 20′ in a flip-chip manner.

The encapsulating 23 is formed on the wiring layer 20′ and the second surface 25b of the insulating layer 25 for covering the electronic components 22.

In an embodiment, the wiring layer 20′ is defined as for providing electrical connection means to the electronic components 22. The terminal surfaces 21a of the conductive pillars are defined as external connection pads.

In an embodiment, the terminal surfaces of the conductive pillars are flush with the first surface of the insulating layer (not shown).

In an embodiment, the package structure 2 further comprises a plurality of conductive elements 24 that are coupled to the first surface 25a of the insulating layer 25 and electrically connected with the terminal surfaces 21a of the conductive pillars 21.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A package structure, comprising:
an insulating layer having opposing first and second surfaces;
a plurality of conductive pillars embedded in the insulating layer and having terminal surfaces exposed from the first surface of the insulating layer;
a wiring layer formed on the second surface of the insulating layer and electrically connected with the conductive pillars;
at least one electronic component disposed on and electrically connected with the wiring layer; and
an encapsulating layer formed on the wiring layer and the second surface of the insulating layer and encapsulating the at least one electronic component.

2. The package structure of claim 1, wherein the terminal surfaces of the conductive pillars are defined as external connection pads.

3. The package structure of claim 1, wherein the terminal surfaces of the conductive pillars are flush with the first surface of the insulating layer.

4. The package structure of claim 1, wherein the at least one electronic component is an active component, a passive component, or a combination thereof.

5. The package structure of claim 1, wherein the at least one electronic component is electrically connected with the wiring layer in a flip-chip manner.

6. The package structure of claim 1, further comprising a plurality of conductive elements formed on the terminal surfaces of the conductive pillars exposed from the first surface of the insulating layer and electrically connected with the conductive pillars.

7. A method of fabricating a package structure, comprising:
forming a plurality of conductive pillars on a conductive layer;
forming on the conductive layer and the conductive pillars an insulating layer that has opposing first and second surfaces, with terminal surfaces of the conductive pillars exposed from the first surface of the insulating layer;
removing a portion of the conductive layer, such that a remaining portion of the conductive layer serves as a wiring layer;
disposing on the wiring layer at least one electronic component that is electrically connected with the wiring layer; and
forming on the wiring layer and the second surface of the insulating layer an encapsulating layer that encapsulates the at least one electronic component.

8. The method of claim 7, wherein the terminal surfaces of the conductive pillars are defined as external connection pads.

9. The method of claim 7, wherein the terminal surfaces of the conductive pillars are flush with the first surface of the insulating layer.

10. The method of claim 7, wherein the at least one electronic component is an active component, a passive component, or a combination thereof.

11. The method of claim 7, wherein the at least one electronic component is electrically connected with the wiring layer in a flip-chip manner.

12. The method of claim 7, further comprising a plurality of conductive elements formed on the terminal surfaces of the conductive pillars exposed from the first surface of the insulating layer and electrically connected with the conductive pillars.

13. A method of fabricating a package structure, comprising:
forming a plurality of conductive pillars on a conductive layer;
forming on the conductive layer and the conductive pillars an insulating layer that has opposing first and second surfaces, with the conductive pillars covered by the insulating layer completely;
removing a portion of the insulating layer, to allow terminal surfaces of the conductive pillars to be exposed from the first surface of the insulating layer;
removing a portion of the conductive layer, such that a remaining portion of the conductive layer serves as a wiring layer;
disposing on the wiring layer at least one electronic component that is electrically connected with the wiring layer; and
forming on the wiring layer and the second surface of the insulating layer an encapsulating layer that encapsulates the at least one electronic component.

14. The method of claim 13, wherein the terminal surfaces of the conductive pillars are defined as external connection pads.

15. The method of claim 13, wherein the terminal surfaces of the conductive pillars are flush with the first surface of the insulating layer.

16. The method of claim 13, wherein the at least one electronic component is an active component, a passive component, or a combination thereof.

17. The method of claim 13, wherein the at least one electronic component is electrically connected with the wiring layer in a flip-chip manner.

18. The method of claim 13, further comprising a plurality of conductive elements formed on the terminal surfaces of the conductive pillars exposed from the first surface of the insulating layer and electrically connected with the conductive pillars.
